(19) United States
(12) Patent Application Publication
(10) Pub. No.: US 2016/0108522 A1
(43) Pub. Date: Apr. 21, 2016

(54) VAPOR INFUSION SYSTEM

(71) Applicants: Brian Donovan, Vancouver, WA (US); Ray McKaig, Vancouver, WA (US)

(72) Inventors: Brian Donovan, Vancouver, WA (US); Ray McKaig, Vancouver, WA (US)

(21) Appl. No.: 14/919,517

(22) Filed: Oct. 21, 2015

Related U.S. Application Data
(60) Provisional application No. 62/066,717, filed on Oct. 21, 2014.

(51) Int. Cl. C23C 16/455; C23C 16/44

(52) U.S. Cl. CPC C23C 16/455; C23C 16/4412

(57) ABSTRACT

This invention is an improved treatment process and apparatus for smoothing and strengthening plastic parts, and particularly parts made by rapid prototyping machines.

### CROSS-REFERENCE TO RELATED APPLICATION

Referring to the application data sheet filed herewith, this application claims a benefit of priority under 35 U.S.C. 119(e) from copending provisional patent application U.S. Ser. No. 62/066,717, filed Oct. 21, 2104, the entire contents of which are hereby expressly incorporated herein by reference for all purposes.

### BACKGROUND

Plastic parts have been sealed by spraying and dipping in liquids, such as acetone for ABS parts. Unfortunately, this results in loss of details, particularly in corners where the liquid acetone accumulates. Because of the porousness of the parts, the liquid penetrates the parts and uncontrolled melting continues inside, even after removal of surface acetone. This results in unacceptable dimensional distortions. Another effect is a discoloration that usually appears like a white frost.

### SUMMARY

There is a need for the following embodiments of the present disclosure. Of course, the present disclosure is not limited to these embodiments.

According to an embodiment of the present disclosure, a process comprises: finishing 3-D prints with potentially explosive vapors safely contained in a vapor chamber including at least one side and at least one lid coupled to the at least one side; and reducing arbitrary condensation dripping from the lid with a vapor condenser located on an inside surface of the lid. According to another embodiment of the present disclosure, a machine comprises: a vapor containment chamber for finishing 3-D prints with potentially explosive vapors safely contained, the vapor chamber including at least one side and at least one lid coupled to the at least one side and a vapor condenser located on an inside surface of the compression lid reducing arbitrary condensation dripping from the lid.

These, and other, embodiments of the present disclosure will be better appreciated and understood when considered in conjunction with the following description and the accompanying drawings. It should be understood, however, that the following description, while indicating various embodiments of the present disclosure and numerous specific details thereof, is given for the purpose of illustration and does not imply limitation. Many substitutions, modifications, additions and/or rearrangements may be made within the scope of embodiments of the present disclosure, and embodiments of the present disclosure include all such substitutions, modifications, additions and/or rearrangements.

### BRIEF DESCRIPTION OF THE DRAWINGS

The drawings accompanying and forming part of this specification are included to depict certain embodiments of the present disclosure. A clearer concept of the embodiments described in this application will be readily apparent by referring to the exemplary, and therefore nonlimiting, embodiments illustrated in the drawings (wherein identical reference numerals (if they occur in more than one view) designate the same elements). The described embodiments may be better understood by reference to one or more of these drawings in combination with the following description presented herein. It should be noted that the features illustrated in the drawings are not necessarily drawn to scale.

FIG. 1 is a front perspective view of a vapor tank.

FIG. 2 is a rear perspective view of a vapor tank.

FIG. 3 is a side perspective view of a vapor tank opened.

FIG. 4 is a top perspective view of a vapor tank with part tray removed.

FIG. 5 is a perspective view of a part tray with part hanger tray removed.

FIG. 6 is an exploded perspective view of a control module.

FIG. 7 is an exploded perspective view of a vapor tank.

FIG. 8 is an exploded perspective view of a vapor condenser assembly.

FIG. 9 is a perspective view of an alternate vapor tank embodiment coupled to a drying chamber.

FIG. 10 is a flow diagram of an operation process that can be implemented by a computer program.

FIG. 11 is a flow diagram of a smoothing interrupt process that can be implemented by a computer program.

FIG. 12 is a view of exemplary control algorithms.

FIG. 13 is view of an operational fan RPM chart.

### DETAILED DESCRIPTION

Embodiments presented in the present disclosure and the various features and advantageous details thereof are explained more fully with reference to the nonlimiting embodiments that are illustrated in the accompanying drawings and detailed in the following description. Descriptions of well known materials, techniques, components and equipment are omitted so as not to unnecessarily obscure the embodiments of the present disclosure in detail. It should be understood, however, that the detailed description and the specific examples are given by way of illustration only and not by way of limitation. Various substitutions, modifications, additions and/or rearrangements within the scope of the underlying inventive concept will become apparent to those skilled in the art from this disclosure.

In general, the embodiments of the disclosure relate to features associated with vapor phase etching that are advantageous to smoothing and sealing 3-D printed parts (work-pieces) especially when those work-pieces are mesoporous. For instance, useful stable vapor solvent classes (e.g. ketones like acetone) can be used to smooth work-piece materials (e.g. styrenics like ABS). Acrylonitrile butadiene styrene (ABS) can be sealed with 1,2 Dichloroethane vapor, Acetone vapor, Cyclohexanone vapor and/or MEK vapor. Polyacetal (Delrin-POM) can be sealed with MEK vapor and/or Methyl benzene vapor.

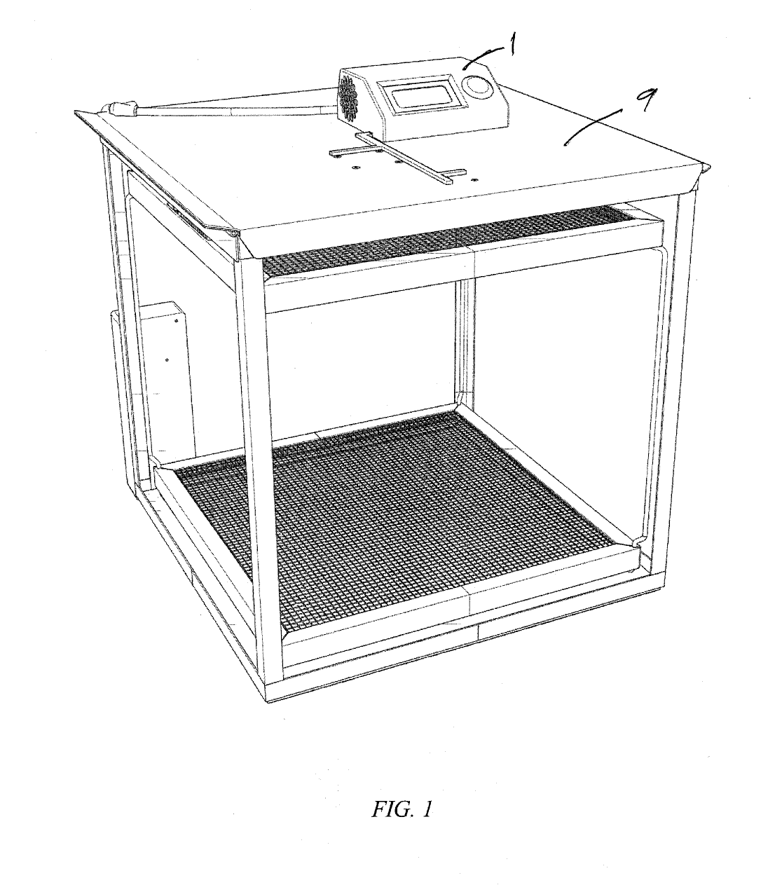

FIG. 1 shows the tank front view with a parts tray inside. The tank is 4 sheets of glass with blast contaminant film applied, and has an aluminum bottom. Silicone rubber or other solvent resistant adhesive is used in the edges and corners to secure the glass and bottom aluminum. Extruded aluminum edge pieces are glued to secure the film and strengthen the box. A hinged aluminum top with an elastomer seal contains the acetone solvent vapor in normal operations. A controller box 1 is coupled to vapor tank lid 9.

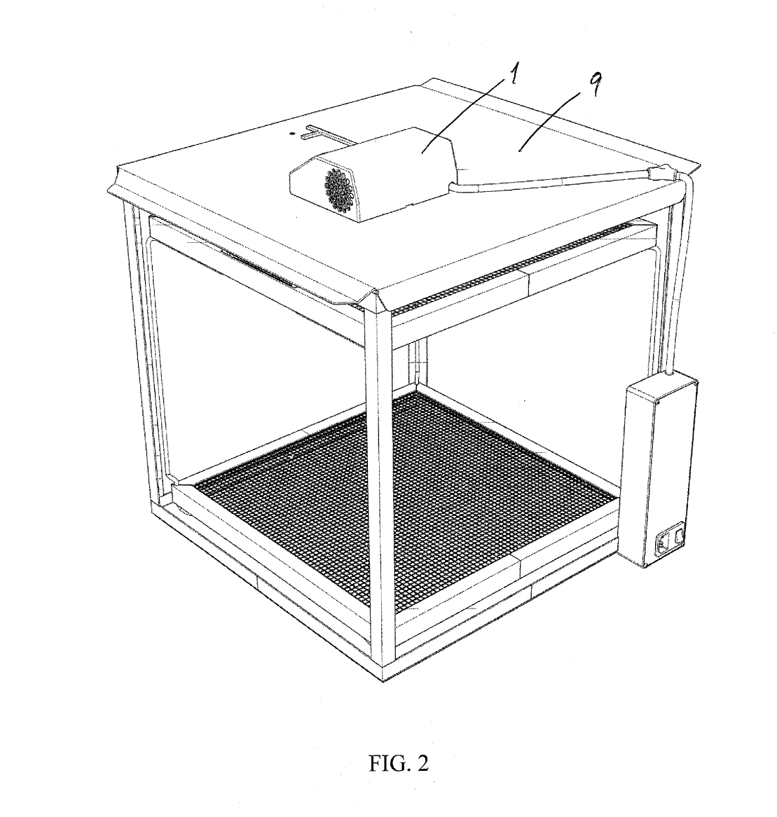

FIG. 2 shows the tank rear view with the parts tray inside. This invention uses a closed clear glass tank with an external blast film applied to allow safe viewing of the progress of parts being treated. A light-weight cover keeps the vapor contained but allows any possible vapor ignition to open the lid, thus reducing pressure to prevent possible explosion. Optionally a magnetic latch may be included to prevent easy opening of the tank in a way that exposes the user to excessive vapors. A heating pad under the tank controls the tank temperature. Instead of using direct liquid contact, this invention uses only vapor for treating parts. A fan provides homogeneous saturation of solvent vapors that prevents layering of air and solvent vapor for uniform part treatment. A computer module on the lid controls the process and helps calculate the proper time for the desired smoothing, controls the fan motor, lamp and tank temperature, and sounds an alarm to notify the user to remove the parts upon completion of the process. If the delay is too long, the alarm becomes loud and insistent.

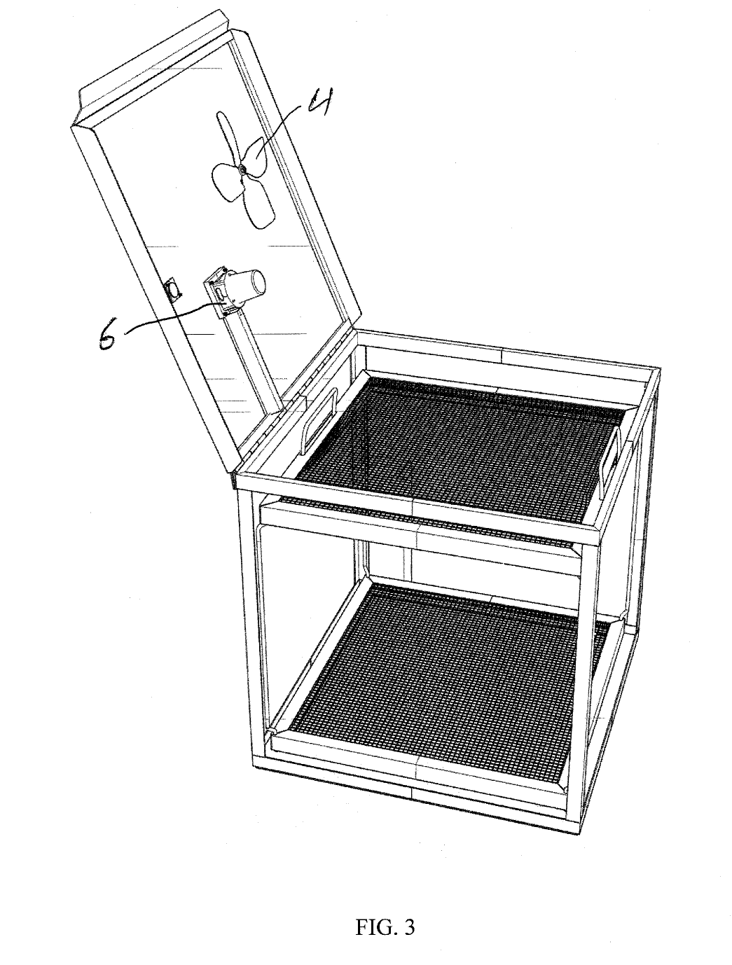

FIG. 3 shows the open tank, Condenser Assembly 6, LED Lamp, and stirring fan 4 that speeds processing and prevents the vapors from layering. An electronic cooling device in the top prevents liquid solvent from dripping on the parts by concentrating condensation to one location. Dripping condensate is measured in a graduated cup that gives a visual indicator of proper tank operation. The cumulative condensate level in the cup is proportional to the smoothing effect on the parts. Upon opening the lid, the graduated cup is automatically emptied.

High-intensity LED light(s) are provided for viewing the smoothing process and are mounted to the aluminum lid which serves as a heat sink The LED light(s) enhance observation of the smoothing process without the need for external lighting.

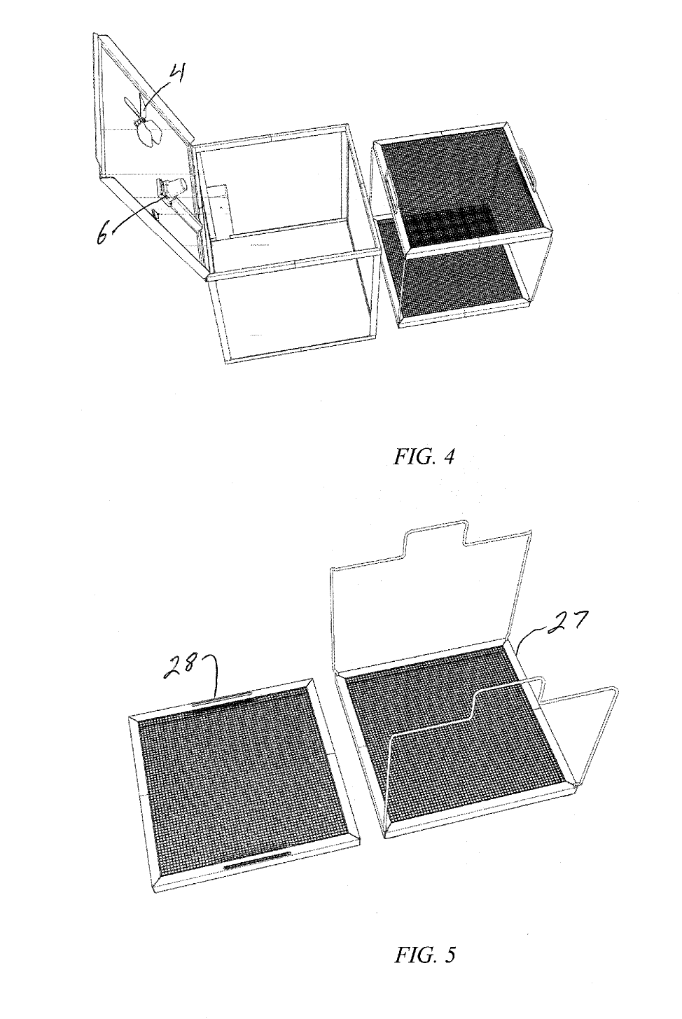

FIG. 4 shows the tank with the parts tray removed. The inside-bottom of the tank may be covered with a disposable sheet of paper to capture contaminants for easy removal. FIG. 5 shows parts tray 27 with the top hanger tray 28 removed.

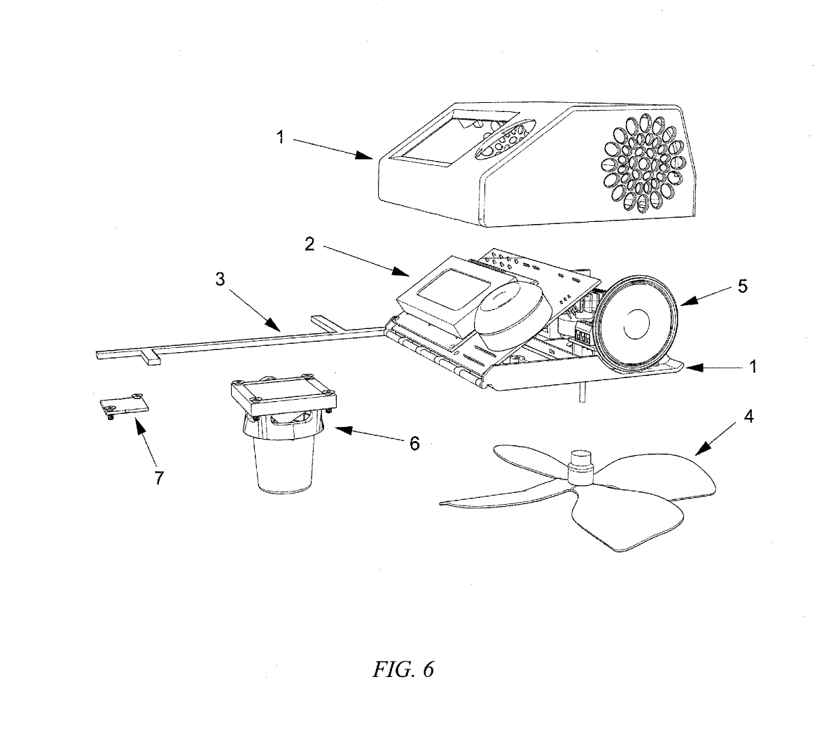

FIG. 6 shows control module and associated parts. The control module includes a controller box 1 that is coupled to a control board 2. A wire protector for condenser and LED lamp 3 is coupled to the control board 2. An aluminum fan blade 4 is coupled to the control board 2. A speaker 5 is coupled to the control board 2. A condenser assembly 6 is coupled to the control board 2. A high intensity LED Lamp 7 is coupled to the control board 2.

The Fan assembly includes a low-voltage brushless motor to eliminate any electric arcing as a possible source of ignition. The fan motor is variable speed to adapt to different parts and requirements. The Fan is composed of metal, wood or other solvent resistant material. The shaft driving the fan is sealed with a greased elastomer washer to create a vapor tight seal.

The controller allows the user to select the amount of smoothing desired (Sheen value), alarm music, fan speed, lamp intensity, and other parameters as desired. These settings are remembered in internal flash memory and need setting only once.

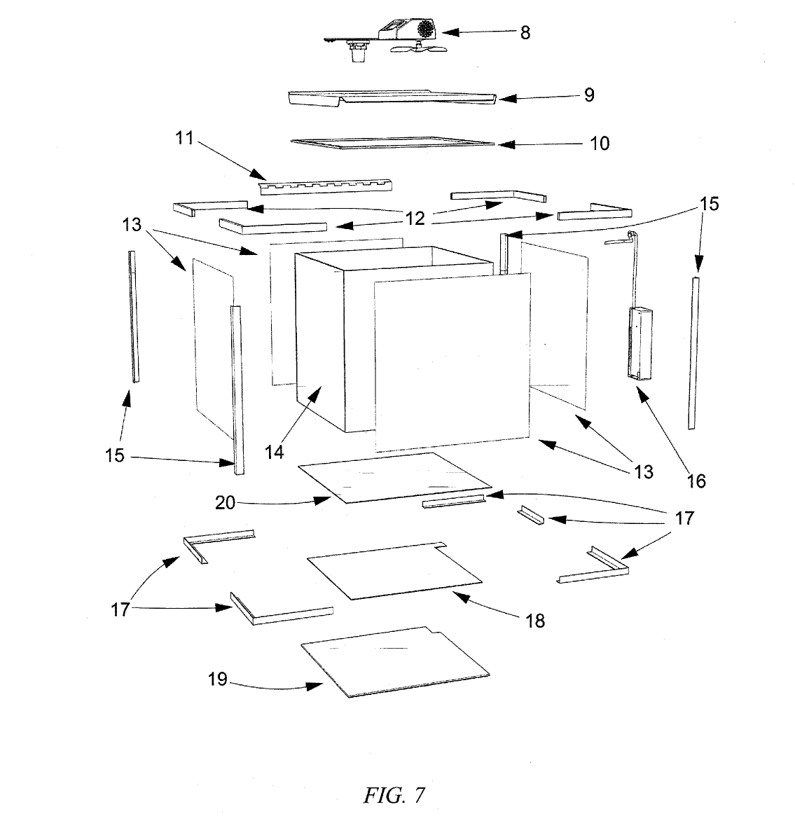

FIG. 7 shows exploded vapor tank parts. A control module assembly 8 is coupled to a vapor tank lid 9. A vapor seal 10 and a hinge 11 are coupled to the vapor tank lid 9. A vapor tank top rim 12 is coupled to the vapor seal 10. A clear blast film 13 is coupled to a glass tank 14. Aluminum side molding 15 is coupled to the clear blast film 13. A power module 16 controls vapor tank heater 18 and provides 12V to control computer module assembly 8. Aluminum Bottom Molding 17 is coupled to the clear blast film 13. Rubber base mat 19 is located within glass tank 14. Aluminum vapor tank bottom 20 is coupled to vapor tank heater 18.

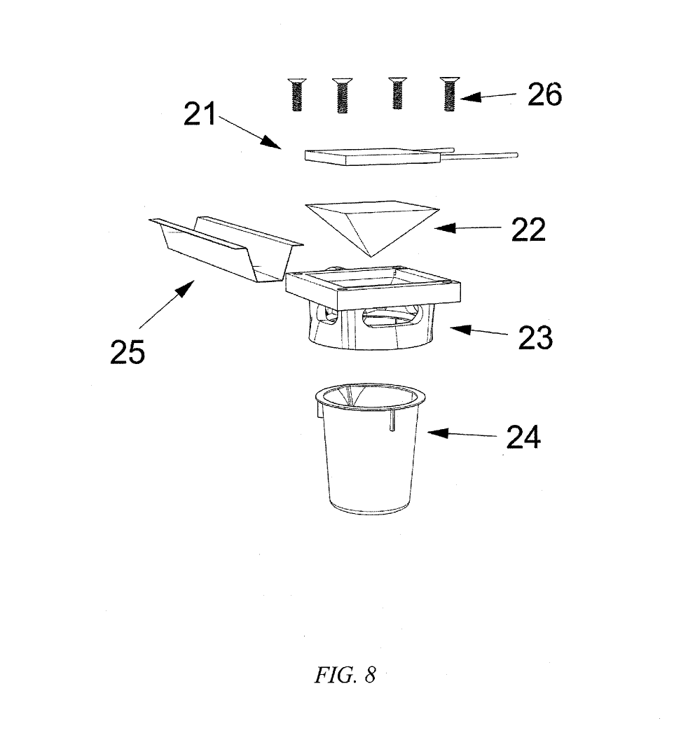

FIG. 8 shows the vapor condenser assembly 6 including solid state refrigerator 21 and concentrating cone 22. The apex of concentrating cone 22 is an example of a cool spot. A housing 23 is coupled to a graduated cup 24. A drain pipe 25 is coupled to housing 23. Mounting screws 26 connect solid state refrigerator 21 to housing 23.

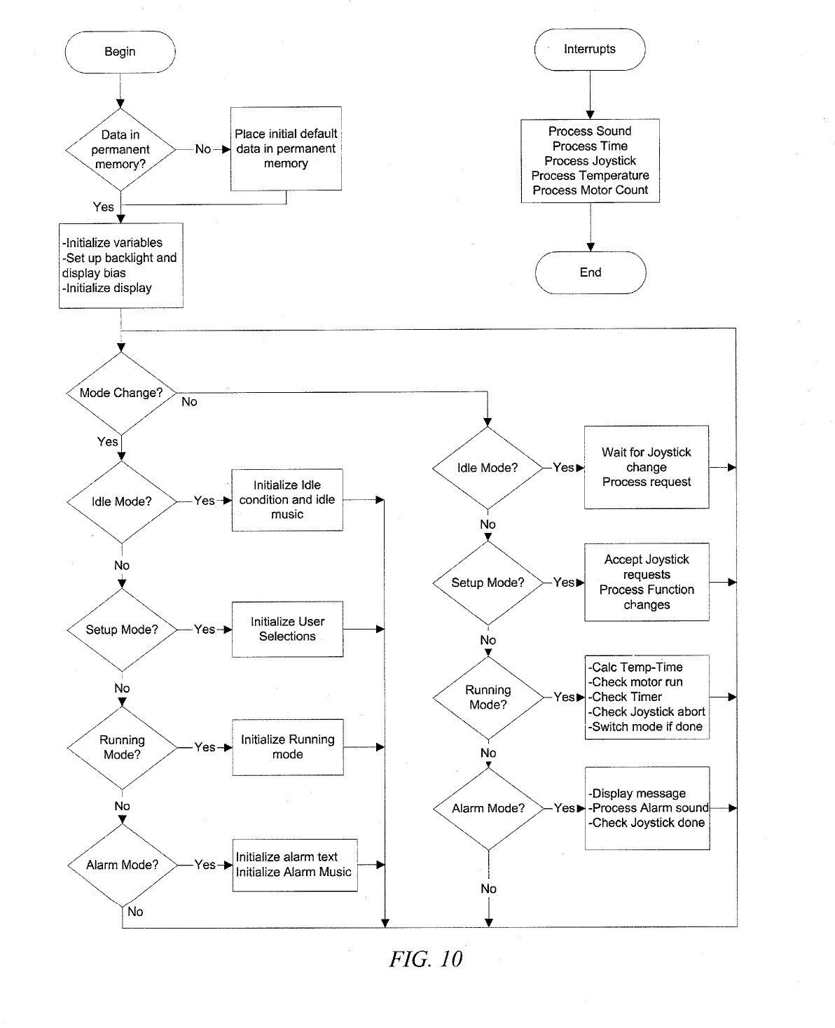

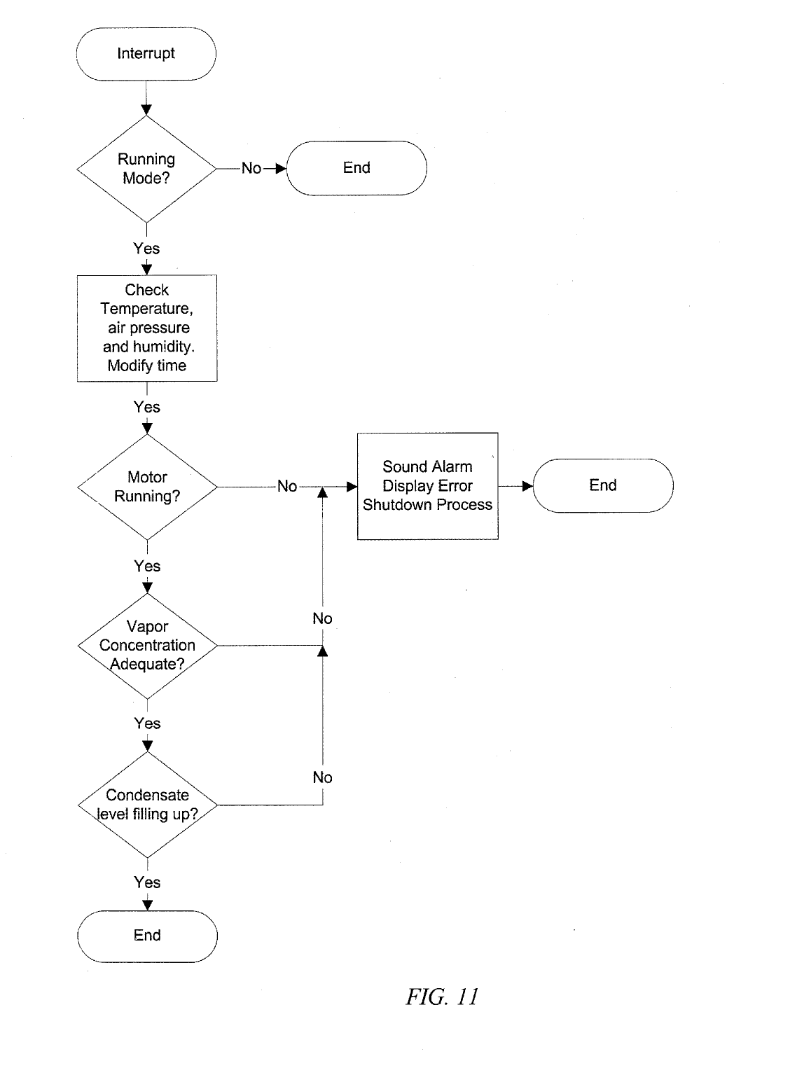

FIGS. 10 and 11 show computer operational flowcharts. FIG. 10 is a General Computer Operation Flowchart. FIG. 11 is a Smoothing Interrupt Flowchart.

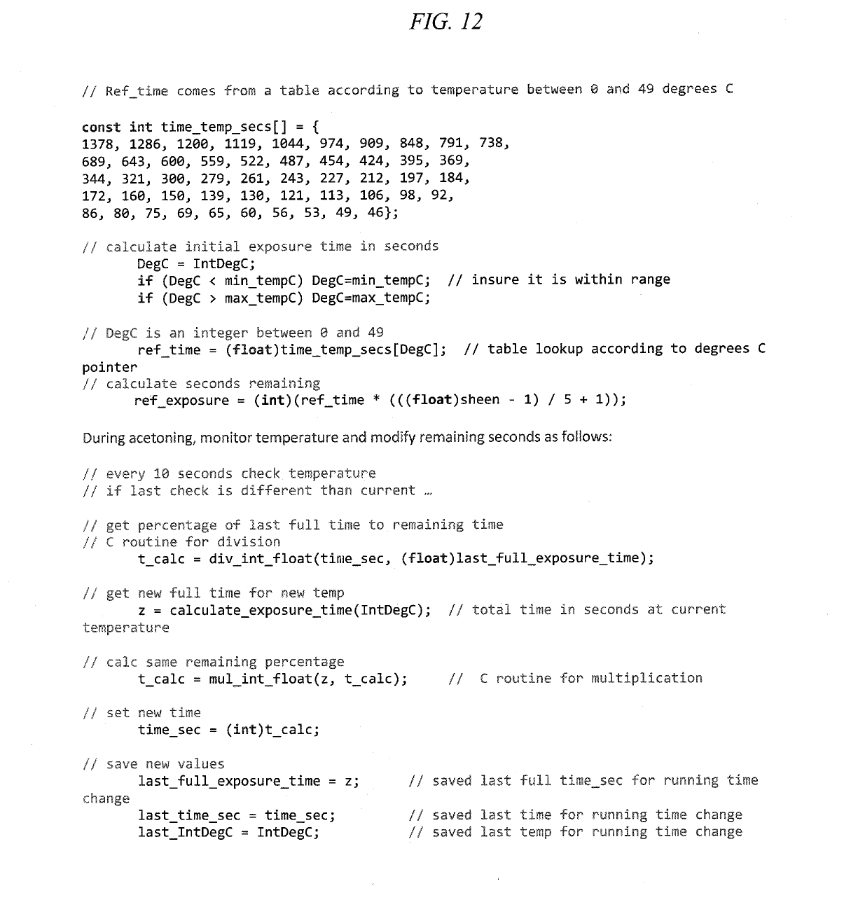

FIG. 12 shows program control algorithms. Those program control algorithms are also recited below to ensure completeness.

```
// Ref_time comes from a table according to temperature between 0 and 49 degrees C
const int time_temp_secs[ ] = {
1378, 1286, 1200, 1119, 1044, 974, 909, 848, 791, 738,
689, 643, 600, 559, 522, 487, 454, 424, 395, 369,
344, 321, 300, 279, 261, 243, 227, 212, 197, 184,
172, 160, 150, 139, 130, 121, 113, 106, 98, 92,
86, 80, 75, 69, 65, 60, 56, 53, 49, 46};
// calculate initial exposure time in seconds
      DegC = IntDegC;
      if (DegC < min_tempC) DegC=min_tempC;  // insure it is within range
      if (DegC > max_tempC) DegC=max_tempC;
// DegC is an integer between 0 and 49
      ref_time = (float)time_temp_secs[DegC];  // table lookup according to degrees
C pointer
// calculate seconds remaining
      ref_exposure = (int)(ref_time * (((float)sheen − 1) / 5 + 1));
During acetoning, monitor temperature and modify remaining seconds as follows:
// every 10 seconds check temperature
// if last check is different than current ...
// get percentage of last full time to remaining time
// C routine for division
      t_calc = div_int_float(time_sec, (float)last_full_exposure_time);
// get new full time for new temp
```

| | |
|---|---|
| z = calculate_exposure_time(IntDegC); | // total time in seconds at current |
| temperature | |
| // calc same remaining percentage | |
| t_calc = mul_int_float(z, t_calc); | // C routine for multiplication |
| // set new time | |
| time_sec = (int)t_calc; | |
| // save new values | |

| | |
|---|---|
| last_full_exposure_time = z; | // saved last full time_sec for running |
| time change | |
| last_time_sec = time_sec; | // saved last time for running time change |
| last_IntDegC = IntDegC; | // saved last temp for running time change |

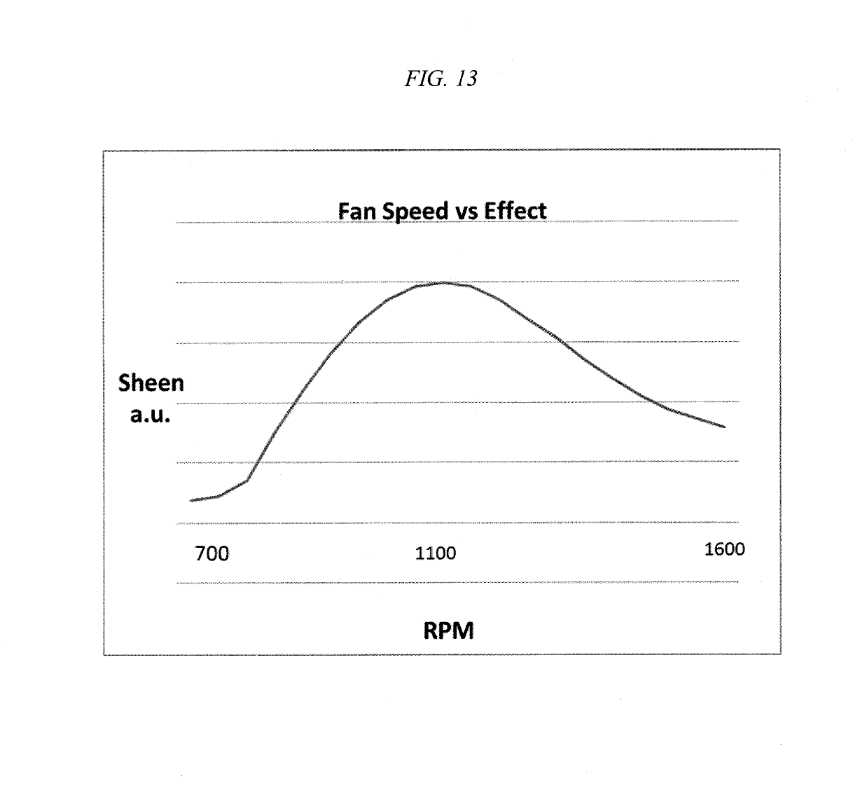

FIG. 13 shows an Operational Fan RPM Chart. Experimentally the inventors observed an optimum mixing energy. Changing (varying) the mixing energy between: (from) 1) enough to prevent stratification of the vapor and coincidence non uniform part treatment and (to) 2) the maximum mixing energy our system can provide shows a distinct optimum, with decreased part treatment rates below and above that optimum level. Pressure loss increases as the square of the velocity. The flow rate caused by the mixing fan has multiple effects. It speeds the evaporation of the solvent, homogenizes the vapor density, and transfers the vapor saturated air through the parts to be treated. As the mixing energy is increased, parts will start to move around, bang into each other, and low pressure areas will be created that will actually reduce smoothing in “shadowed” areas. Thus, there is an optimum mixing energy, and an optimum fan RPM to achieve that as depicted in the chart.

Exposure times are calculated by formula. Arrhenius temperature dependence, the effect of temperature on the reaction rate k, is found to be exponential as the following formula describes:

k=k0*ê(−E/RT)

where: k0 a pre-exponential (Arrhenius) factor.
E is the activation energy,
R is the universal gas constant.
T is Temperature in K.

Thus, this invention automatically controls the tank temperature, plus measures it and corrects the exposure time to achieve a repeatable level of smoothing. Alternatively, a mode may be selected that allows the user to select a fixed time duration manually.

The user enters the sheen (smoothing factor) desired and the controller calculates the time. The user places the parts in the tank and starts the treatment by activating the controller. During the smoothing process, the controller adjusts the time remaining to compensate for temperature changes. When the time is up, a musical alert is sounded which progressively provides louder and more attention getting sound sequences while flashing the light. The User stops the process by pressing the button on the controller, and the music and fan stops. Then the user removes the parts and sets them aside to dry. Because the tank offers unparalleled visibility of the progress and is internally lighted, the user may elect to watch the treatment and stop it at any time they choose. There is some minor continuation of the melting after removal from the tank, but it is far less than with liquid based systems. Multiple treatments may be used to alter smoothing effects. The first treatment will treat all the way through porous parts, and will seal them so that future treatments affect the surface rather than the part interior.

The controller is built with a user replaceable computer chip to allow for future updates and possible alternate part types and solvents.

Description of an Alternate Embodiment:

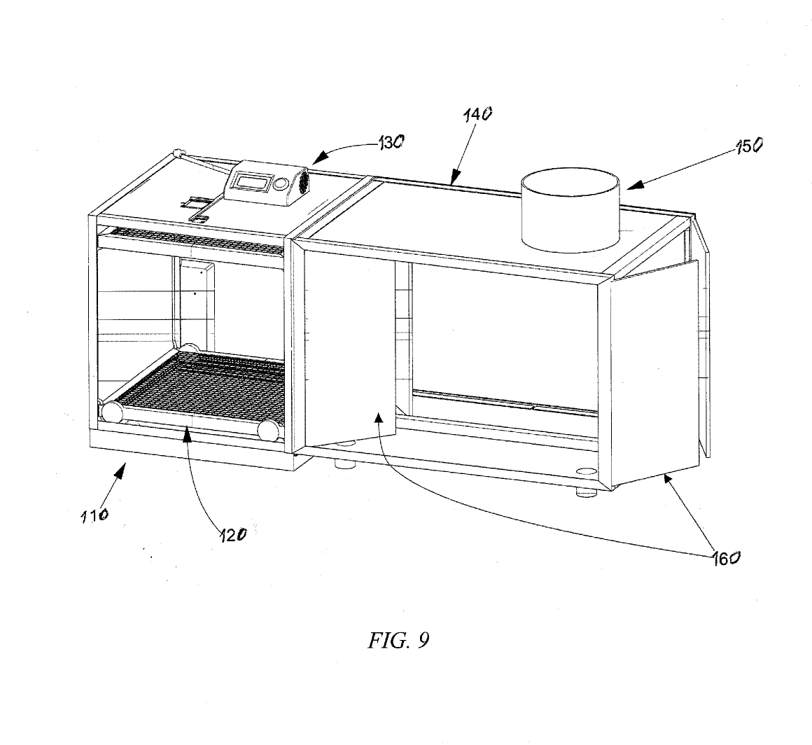

FIG. 9 shows alternate embodiment of industrial use Vapor Tank. A vapor tank exposure section 110 is shown containing a rolling parts tray 120. A control module 130 is located above the vapor tank exposure section 110. A vapor exhaust and parts removal tank 140 is coupled to the vapor tank exposure section 110. The vapor exhaust and parts removal tank 140 is coupled to an exhaust vent 150. The vapor exhaust and parts removal tank 140 has vapor sealing doors 160.

The main tank section is similar to the preferred embodiment with a flow-through assembly line for continuous part processing. Parts are introduced to the tank on a rolling parts tray and exposed. Upon process completion, vapor lock doors open and the parts tray is shifted into the Vapor exhaust and Parts Removal tank, at which time a new parts tray is introduced into the main tank section for the next load of parts to be processed. Once the vapors are exhausted, the processed parts are removed.

List of Solvent Cross Materials:

Nearly any plastic can be smoothed with some solvent or combination of solvents. Patent U.S. Pat. No. 4,529,563A for instance explores the various plastics and effective smoothing agents for use with each, plus lays out a strategy for finding appropriate solvents for a given plastic. The entire contents of U.S. Pat. No. 4,529,563 are hereby expressly incorporated by reference herein for all purposes.

As noted above, acrylonitrile butadiene styrene (ABS) can be sealed with 1,2 Dichloroethane vapor, Acetone vapor, Cyclohexanone vapor and/or MEK vapor. Polyacetal (Delrin-POM) can be sealed with MEK vapor and/or Methyl benzene vapor. Polycarbonate can be smoothed with minimal loss of strength using Azeotropic (vapor) mixtures of meta xylene and iso-amyl acetate that are formed by a mixture that is 46% xylene and 54% amyl acetate at 136° C. A vapor mixture of 44.87% butyl alcohol and 55.2% butyl acetate at 113° C. also works on polycarbonate.

List of Independent Process Variables That Can be Controlled to Improve Performance and Repeatability:
1. Temperature
2. Humidity
3. Partial pressure of solvents
4. Illumination intensity and wavelength
5. Mixing energy

User Operational Sequence:
1. Turn on unit, put acetone or other liquid or gas in the tank.
2. Adjust processing exposure values as desired.
3. Place the parts in the tank using the parts tray or optionally using a user-supplied holder.
4. Close the lid, push start.
5. Upon alarm sounding, push stop and remove the parts.

Controller Operational Sequence:

During system operation, the computer controls the smoothing process automatically:
1. Turns on the fan, light, and heater, starts the timer
2. Monitors the temperature, optionally measure saturation, and computes when the proper level of treatment has been achieved.
3. Upon completion, turns off the heat for about a minute before the predicted finishing time and keeps the fan going to condense out and cool the vapor in the tank
4. Upon total completion time:
   a. turns off the fan
   b. flashes the lamp
   c. sounds the alarm music
   d. as time progresses without user interaction, the alarm changes to an attention-getting series of musical sequences, getting louder.
In the above embodiment, the user turns off the controller and removes the parts tray for drying.

An embodiment can include a clear tank for treating parts with potentially explosive vapors safely contained using blast film and a low compression lid. An embodiment can include a vapor treatment system with a controller that continually adjusts for changing environment parameters such as temperature, or humidity. An embodiment can include a spot cooling system to control and measure top condensation that is automatically cleared each time the unit is opened. An embodiment can include an electronic measurement of the cumulative condensation used by the computer to optimize treatment time. Sensing liquid levels may be achieved by but is not limited to the following methods: ultrasonic, optical, float, mass, capacitive and/or inductive. An embodiment can include localized controlled condensation that prevents arbitrary condensation dripping from the lid onto the parts. In a preferred embodiment use is made of pettier (Peltier) cooling chips. Alternative condenser configurations: water cooled or use the whole lid condenser hemisphere with collector around the rim, chiller based with coils, evaporator based cooling, air impingement and vortex tube cooling, ice or dry ice cooling and/or ambient heat sink attached to collection spot. Alternate tank versions include automatic insertion and removal from vapors to an exhaust drying area. Alarm when process is done, that increases in intensity and speed with time. Vapor sensors can be added as needed to improve accuracy of computer controlled exposure.

An embodiment can include lowering the temperature and changing other parameters such as fan speed and partial pressure alters vapor penetration deeper into the parts, variations in smoothing, and treating part internal structures. An embodiments can include a fan the prevents layering of vapors and resulting uneven exposure. Use of Brushless low voltage motor removes possible ignition source. All of the electronics are also low voltage for the same reasons. Lowering the temperature, allows vapor penetrating deeper into the parts and smoothing, and treating the internals.

The two chamber embodiment, allows automation of the entire sequence, form insertion, to multiple exposures, to final drying. The two chamber embodiment allows integrating into an assembly line and automation. The two chamber embodiment eliminates vapor exposure for users.

### Definitions

The term vapor is intended to mean a solid and/or liquid in equilibrium with a gas phase; and this is intended to preclude just a gas in the absence of a solid and/or liquid as well as also precluding a solid and/or liquid in the absence of a gas. The terms program and software and/or the phrases program elements, computer program and computer software are intended to mean a sequence of instructions designed for execution on a computer system (e.g., a program and/or computer program, may include a subroutine, a function, a procedure, an object method, an object implementation, an executable application, an applet, a servlet, a source code, an object code, a shared library/dynamic load library and/or other sequence of instructions designed for execution on a computer or computer system).

The term uniformly is intended to mean unvarying or deviate very little from a given and/or expected value (e.g. within 10% of). The term substantially is intended to mean largely but not necessarily wholly that which is specified. The term approximately is intended to mean at least close to a given value (e.g., within 10% of). The term generally is intended to mean at least approaching a given state. The term coupled is intended to mean connected, although not necessarily directly, and not necessarily mechanically. The term proximate, as used herein, is intended to mean close, near adjacent and/or coincident; and includes spatial situations where specified functions and/or results (if any) can be carried out and/or achieved. The term distal, as used herein, is intended to mean far, away, spaced apart from and/or non-coincident, and includes spatial situation where specified functions and/or results (if any) can be carried out and/or achieved. The term deploying is intended to mean designing, building, shipping, installing and/or operating.

The terms first or one, and the phrases at least a first or at least one, are intended to mean the singular or the plural unless it is clear from the intrinsic text of this document that it is meant otherwise. The terms second or another, and the phrases at least a second or at least another, are intended to mean the singular or the plural unless it is clear from the intrinsic text of this document that it is meant otherwise. Unless expressly stated to the contrary in the intrinsic text of this document, the term or is intended to mean an inclusive or and not an exclusive or. Specifically, a condition A or B is satisfied by any one of the following: A is true (or present) and B is false (or not present), A is false (or not present) and B is true (or present), and both A and B are true (or present). The terms a and/or an are employed for grammatical style and merely for convenience.

The term plurality is intended to mean two or more than two. The term any is intended to mean all applicable members of a set or at least a subset of all applicable members of the set. The phrase any integer derivable therein is intended to mean an integer between the corresponding numbers recited in the specification. The phrase any range derivable therein is intended to mean any range within such corresponding numbers. The term means, when followed by the term “for” is intended to mean hardware, firmware and/or software for achieving a result. The term step, when followed by the term “for” is intended to mean a (sub)method, (sub)process and/or (sub)routine for achieving the recited result. Unless otherwise defined, all technical and scientific terms used herein have the same meaning as commonly understood by one of ordinary skill in the art to which this present disclosure belongs. In case of conflict, the present specification, including definitions, will control.

The described embodiments and examples are illustrative only and not intended to be limiting. Although embodiments of the present disclosure can be implemented separately, embodiments of the present disclosure may be integrated into the system(s) with which they are associated. All the embodiments of the present disclosure disclosed herein can be made and used without undue experimentation in light of the disclosure. Embodiments of the present disclosure are not limited by theoretical statements (if any) recited herein. The individual steps of embodiments of the present disclosure need not be performed in the disclosed manner, or combined in the disclosed sequences, but may be performed in any and all manner and/or combined in any and all sequences. The individual components of embodiments of the present disclosure need not be formed in the disclosed shapes, or combined in the disclosed configurations, but could be provided in any and all shapes, and/or combined in any and all configurations. The individual components need not be fabricated from the disclosed materials, but could be fabricated from any and all suitable materials.

Various substitutions, modifications, additions and/or rearrangements of the features of embodiments of the present disclosure may be made without deviating from the scope of the underlying inventive concept. All the disclosed elements and features of each disclosed embodiment can be combined with, or substituted for, the disclosed elements and features of every other disclosed embodiment except where such elements or features are mutually exclusive. The scope of the underlying inventive concept as defined by the appended claims and their equivalents cover all such substitutions, modifications, additions and/or rearrangements.

The appended claims are not to be interpreted as including means-plus-function limitations, unless such a limitation is explicitly recited in a given claim using the phrase(s) “means for” or “mechanism for” or “step for”. Sub-generic embodiments of this disclosure are delineated by the appended independent claims and their equivalents. Specific embodiments of this disclosure are differentiated by the appended dependent claims and their equivalents.

What is claimed is:

1. An apparatus, comprising a vapor containment chamber for finishing 3-D prints with potentially explosive vapors safely contained, the vapor chamber including at least one side and at least one lid coupled to the at least one side and a vapor condenser located on an inside surface of the compression lid reducing arbitrary condensation dripping from the lid.

2. The apparatus of claim 1, wherein the vapor condenser includes a cooler to locate at least one condensation drip point above a collection container substantially eliminating arbitrary condensation dripping from the lid.

3. The apparatus of claim 2, wherein the cooler includes a heat sink having at least one member selected from the group consisting of a chiller, an evaporator, a Peltier effect device or convective impingement.

4. The apparatus of claim 2, further comprising a linkage to automatically empty the collection container when the at least one lid is opened.

5. The apparatus of claim 2, further comprising a sensor measuring liquid accumulated in the collection container selected from the group consisting of ultrasonic, optical, float, mass, capacitive or inductive.

6. The apparatus of claim 5, further comprising at least one controller that adjusts at least one dependent variable selected from the group consisting of fan speed, fan time, heater power, heater time, solvent mist spray flow or solvent mist spray time as a function of at least one independent variable selected from the group consisting of temperature, humidity, partial pressure of solvent or liquid accumulated in the collection container.

7. The apparatus of claim 2, wherein the lid includes a hemispherical lid and the cooler is located around an edge of the hemispherical lid.

8. The apparatus of claim 1, wherein the lid includes a compression lid that is coupled to the at least one side with a restorative force exerting linkage, wherein the compression lid safely vents excessive pressure from the vapor containment chamber.

9. The apparatus of claim 1, further comprising a removable part hanger tray that is located inside the vapor containment chamber for smoothing 3-D prints.

10. The apparatus of claim 1, further comprising an exhaust drying chamber coupled to the vapor containment chamber.

11. The apparatus of claim 10, further comprising a transfer conveyance to move parts from the vapor containment chamber to the exhaust drying chamber.

12. The apparatus of claim 1, further comprising an insertion conveyance to load parts into the vapor containment chamber.

13. The apparatus of claim 10, further comprising a removal conveyance to unload parts from the exhaust drying chamber.

14. A method, comprising: finishing 3-D prints with potentially explosive vapors safely contained in a vapor chamber including at least one side and at least one lid coupled to the at least one side; and reducing arbitrary condensation dripping from the lid with a vapor condenser located on an inside surface of the lid.

15. The method of claim 14, further comprising substantially eliminating arbitrary condensation dripping from the lid by including a cooler in the vapor condenser to locate at least one condensation drip point above a collection container.

16. The method of claim 15, further comprising automatically emptying the collection container when the at least one lid is opened.

17. The method of claim 14, further comprising adjusting at least one dependent variable selected from the group consisting of fan speed, fan time, heater power, heater time, solvent mist spray flow or solvent mist spray time as a function of at least one independent variable selected from the group consisting of temperature, humidity, partial pressure of solvent or liquid accumulated in the collection container.

18. The method of claim 14, further comprising locating a removable part hanger tray inside the vapor containment chamber for smoothing 3-D prints.

19. The method of claim 14, further comprising transferring 3-D prints from the vapor containment chamber to an exhaust drying chamber that is coupled to the vapor containment chamber.

20. The apparatus of claim 1, wherein the at least one side includes at least one transparent viewing glass window having a blast resistant plastic film.
